(19) United States
(12) Patent Application Publication
(10) Pub. No.: US 2026/0031803 A1
(43) Pub. Date: Jan. 29, 2026

(54) System, Device, and Method for Correcting a Duty Cycle

(71) Applicant: Taiwan Semiconductor Manufacturing Company, Ltd., Hsinchu (TW)

(72) Inventors: Wei Shuo Lin, Hsinchu (TW); Sheng-Tsung Lai, Hsinchu (TW); Chang-Yi Li, Hsinchu (TW)

(21) Appl. No.: 18/782,073

(22) Filed: Jul. 24, 2024

(51) Int. Cl. H03K 5/156; H03K 3/037

(52) U.S. Cl. CPC H03K 5/1565; H03K 3/037

(57) ABSTRACT

A device includes a clock signal generator and a transmitter circuit. The clock signal generator receives a first input clock signal, generates an output clock signal, and includes a phase generator and a duty cycle corrector. The phase generator generates a plurality of second input clock signals from the input clock signal. The duty cycle corrector adjusts a duty cycle of the second input clock signal with reference to a control signal, generates a single-ended input signal and complementary output signals from the single-ended input signal, compares the complementary output signals, and generates a result of comparison that serves as the control signal. The transmitter circuit receives an input data signal, processes the input data signal in response to the output clock signal, generates an output data signal, and transmits the output data signal.

### BACKGROUND

A duty cycle is the ratio of the duration of the active (or high) state of a signal, e.g., a clock signal, to its period. As high-speed systems or devices continue to advance, achieving a duty cycle of 50%, in which the active state of the signal occupies half of the period, becomes increasingly desirable. These equal durations of the high and low states may facilitate signal integrity and synchronization in their operation.

### BRIEF DESCRIPTION OF THE DRAWINGS

Aspects of the present disclosure are best understood from the following detailed description when read with the accompanying figures:

FIG. 1 is a block diagram of an exemplary system in accordance with various embodiments of the present disclosure;

FIG. 2 is a block/circuit diagram illustrating another exemplary system in accordance with various embodiments of the present disclosure;

FIG. 3 is a block/circuit diagram illustrating an exemplary duty cycle corrector in accordance with various embodiments of the present disclosure;

FIG. 4 is a circuit diagram of an exemplary duty cycle altering circuit in accordance with various embodiments of the present disclosure;

FIG. 5 is a block diagram of an exemplary differential signal generator in accordance with various embodiments of the present disclosure;

FIG. 6 is a circuit diagram of another exemplary differential signal generator in accordance with various embodiments of the present disclosure;

FIG. 7 is a circuit diagram of an exemplary filter circuit in accordance with various embodiments of the present disclosure;

FIG. 8 is a flowchart of an exemplary method for transmitting data in accordance with various embodiments of the present disclosure;

FIG. 9 is a flowchart of an exemplary operation of a method in accordance with the present disclosure;

FIG. 10 is a circuit diagram of another exemplary differential signal generator in accordance with various embodiments of the present disclosure;

FIG. 11 is a flowchart of another exemplary operation of a method in accordance with the present disclosure;

FIG. 12 is a block/circuit diagram illustrating another exemplary duty cycle corrector in accordance with various embodiments of the present disclosure;

FIG. 13 is a circuit diagram of another exemplary duty cycle altering circuit in accordance with various embodiments of the present disclosure;

FIG. 14 is a circuit diagram of an exemplary complementary control signal generator in accordance with various embodiments of the present disclosure;

FIG. 15 is a circuit diagram of an exemplary slave transistor in accordance with various embodiments of the present disclosure;

FIG. 16 is a flowchart of another exemplary method for receiving data in accordance with various embodiments of the present disclosure; and

FIG. 17 is a flowchart of another exemplary operation of a method in accordance with the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As high-speed systems or devices continue to advance, achieving a duty cycle of 50% of a signal, e.g., clock signal. However, maintaining equal durations of high and low states of a clock signal can be challenging due to variations that can occur in the manufacturing process, supply voltage, and operating temperature of devices. To address these challenges, systems, devices, and methods, as described herein, ensure a duty cycle of substantially 50% by employing a single-to-differential converter that converts or transforms a single-ended input signal into complementary output signals, in a manner that will be described hereinafter.

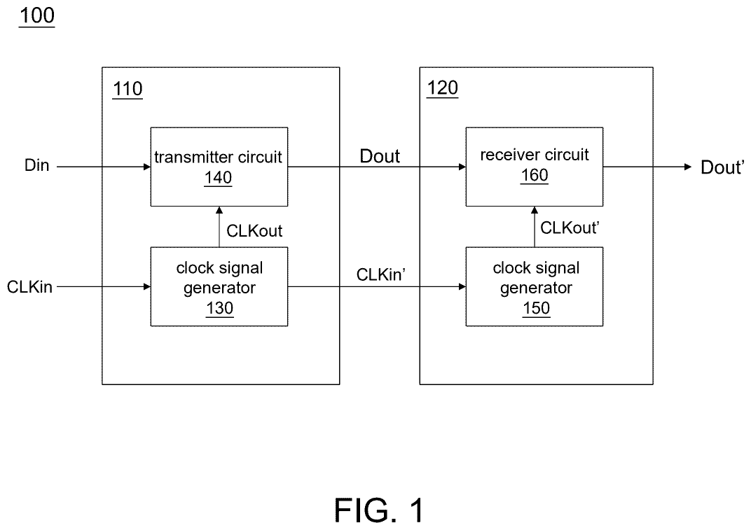

FIG. 1 is a block diagram of an exemplary system 100 in accordance with various embodiments of the present disclosure. As illustrated in FIG. 1, the example system 100 includes a first device 110 and a second device 120 configured to be connected to the output of the first device 110. The device 110 includes a clock signal generator 130 and a transmitter circuit 140. The clock signal generator 130 receives an input clock signal (CLKin) and generates an output clock signal (CLKout) from the input clock signal (CLKin) received thereby such that the output clock signal (CLKout) has a duty cycle of substantially 50%. The transmitter circuit 140 receives an input data signal (Din) along with the output clock signal (CLKout) and processes the input data signal (Din) in response to a logic state (i.e., high ‘1’ or low ‘0’), a transition edge (i.e., rising or falling edge), or a clock period/frequency of the output clock signal (CLKout), and transmits an output data signal (Dout) to the output thereof.

In certain embodiments, the clock signal generator 130 further generates an input clock signal (CLKin′) from the input clock signal (CLKin) received thereby such that the input clock signal (CLKin′) has a substantially 50% duty cycle. In such certain embodiments, the input clock signal (CLKin′) may have a phase different from a phase of the output clock signal (CLKout).

Similarly, the device 120 includes a clock signal generator 150 and a receiver circuit 160. The clock signal generator 150 receives an input clock signal (CLKin′) and generates an output clock signal (CLKout′) from the input clock signal (CLKin′) received thereby such that the output clock signal (CLKout′) has a duty cycle of substantially 50%. The receiver circuit 160 receives an output data signal (Dout) along with the output clock signal (CLKout′), processes the output data signal (Dout) in response to a logic state (i.e., high ‘1’ or low ‘0’), a transition edge (i.e., rising or falling edge), or a clock period/frequency of the output clock signal (CLKout′), and provides an output data signal (Dout′) as an output.

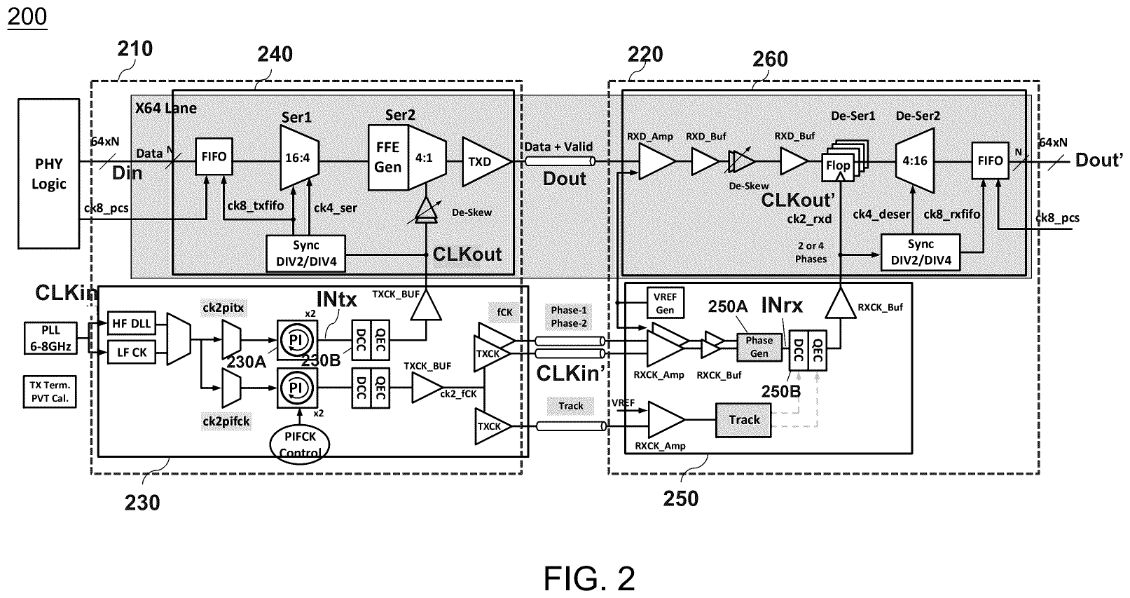

As will be described hereinbelow, each clock signal generator 130, 150 includes a duty cycle corrector (e.g., duty cycle corrector 230B, 250B in FIG. 2). The duty cycle corrector 230B, 250B is implemented with a differential signal generator 320, 1220 that converts a single-ended input signal into complementary output signals. This ensures that the output clock signal (CLKout, CLKout′) has a duty cycle of substantially 50%.

Example supporting circuitry for the system 100 is depicted in FIG. 2. It is understood that this circuitry is provided by way of example, not by limitation, and other suitable system 100 circuitry are within the scope of the present disclosure. FIG. 2 is a block/circuit diagram illustrating another exemplary system 200 in accordance with various embodiments of the present disclosure. As illustrated in FIG. 2, the example system 200 includes a first device 210 and a second device 220 configured to be connected to the output of the first device 210. The device 210 includes a clock signal generator 230 and a transmitter circuit 240. The clock signal generator 230 receives an input clock signal (CLKin) and generates an output clock signal (CLKout) based on the input clock signal (CLKin) received thereby such that the output clock signal (CLKout) has a duty cycle of substantially 50%. For example, the clock signal generator 230 includes a phase generator 230A and a duty cycle corrector 230B. The phase generator 230A employs the input clock signal (CLKin) to generate a plurality of input clock signals (only one of the input clock signals is labeled as INtx in FIG. 2), each having a distinct phase. The duty cycle corrector 230B receives the input clock signal (INtx) and generates an output clock signal (CLKout) based on the single-ended input signal (IN) received thereby such that the output clock signal (CLKout) has a duty cycle of substantially 50%.

In this exemplary embodiment, the transmitter circuit 240 is in the form of a serial-to-parallel converter, receives an input data signal (Din) in a serial format and an output clock signal (CLKout), converts the input data signal (Din) received thereby to a parallel format in response to a logic state (i.e., high ‘1’ or low ‘0’), a transition edge (i.e., rising or falling edge), or a clock period/frequency of the output clock signal (CLKout), and transmits an output data signal (Dout).

The device 220 includes a clock signal generator 250 and a receiver circuit 260. The clock signal generator 250 receives an input clock signal (CLKin′) and generates an output clock signal (CLKout′) based on the input clock signal (CLKin′) received thereby such that the output clock signal (CLKout′) has a duty cycle of substantially 50%. For example, the clock signal generator 250 includes a phase generator 250A and a duty cycle corrector 250B. The phase generator 250A employs the input clock signal (CLKin′) to generate a plurality of input clock signals (only one of the input clock signals is labeled as INrx in FIG. 2), each having a distinct phase. The duty cycle corrector 250B receives the input clock signal (INrx) and generates an output clock signal (CLKout′) based on the single-ended input signal (IN) received thereby such that the output clock signal (CLKout′) has a duty cycle of substantially 50%.

In this exemplary embodiment, the receiver circuit 260 is in the form of a parallel-to-serial converter, receives an output data signal (Dout) in a parallel format and an output clock signal (CLKout′), transforms the output data signal (Dout) received thereby to a serial format in response to a logic state (i.e., high ‘1’ or low ‘0’), a transition edge (i.e., rising or falling edge), or a clock period/frequency of the output clock signal (CLKout′), and provides an output data signal (Dout′) as an output.

Various configurations for the transmitter/receiver circuit 240/260 are contemplated in further embodiments. For example, in an alternative embodiments, the transmitter/receiver circuit 240/260 may process the input data signal (Din, Din′) by encoding/decoding (or by performing any other data manipulation on) the input data signal (Din/Din′).

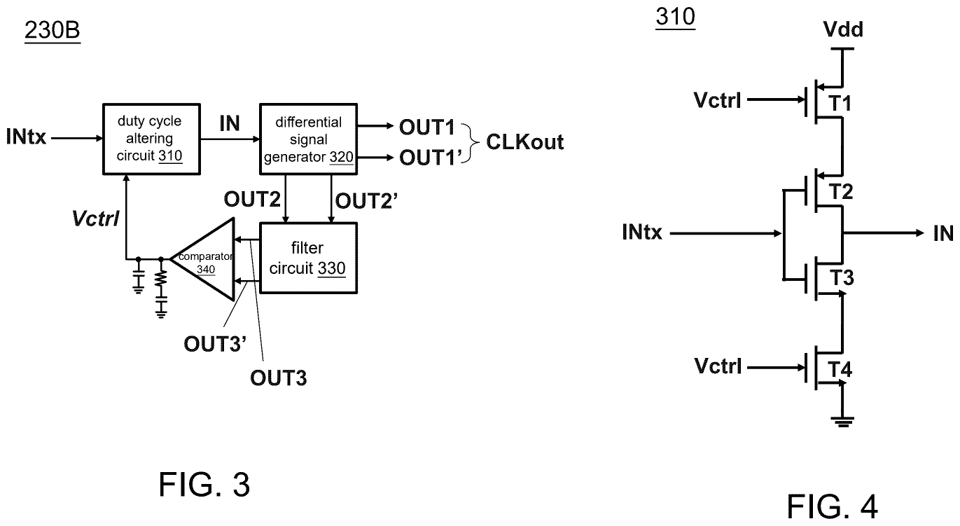

FIG. 3 is a block/circuit diagram illustrating an exemplary duty cycle corrector 230B in accordance with various embodiments of the present disclosure. As illustrated in FIG. 3, the example duty cycle corrector 230B is in the form of an analog circuit and includes a duty cycle altering circuit 310, a differential signal generator 320, a filter circuit 330, and a comparator 340. The duty cycle altering circuit 310 receives an input clock signal (INtx) and a control signal (Vctrl), adjusts (increases or decreases) or maintains the duty cycle of the input clock signal (INtx) in response to the control signal (Vctrl), and generates a single-ended input signal (IN). The differential signal generator 320 receives the single-ended input signal (IN) and converts or transforms the single-ended input signal (IN) into first complementary output signals (OUT1, OUT1′) and second complementary output signals (OUT2, OUT2′). The output clock signal (CLKout) is associated with the complementary output signals (OUT1, OUT1′).

The filter circuit 330 receives the complementary output signal (OUT2, OUT2′) and includes a low pass filter, allowing the complementary output signals (OUT2, OUT2′) with frequencies below a predetermined cutoff frequency to pass through, while attenuating the output signals (OUT2, OUT2′) with frequencies above the predetermined cutoff frequency, and generates complementary output signals (OUT3, OUT3′), each of which corresponds to a respective one of the complementary output signals (OUT2, OUT2′). In some embodiments, the filter circuit 330 includes a high pass filter. In such some embodiments, the filter circuit 330 permits the complementary output signals (OUT2, OUT2′) with frequencies above a predetermined cutoff frequency to pass through, while attenuating the complementary output signals (OUT2, OUT2′) with frequencies below the predetermined cutoff frequency. In other embodiments, the filter circuit 330 includes a bandpass filter. In such other embodiments, the filter circuit 330 enables the complementary output signals (OUT2, OUT2′) with frequencies inside a predetermined frequency range to pass through, while attenuating the complementary output signals (OUT2, OUT2′) with frequencies outside the predetermined frequency range.

The comparator 340, e.g., an operational amplifier, receives one of the complementary output signals (OUT3, OUT3′) at a non-inverting input thereof and the other of the complementary output signals (OUT3, OUT3′) at an inverting input thereof, compares the complementary output signals (OUT3, OUT3′) received thereby, and generates the control signal (Vctrl) that indicates the result of comparison.

FIG. 4 is a circuit diagram of an exemplary duty cycle altering circuit 310 in accordance with various embodiments of the present disclosure. As illustrated in FIG. 4, the example duty cycle altering circuit 310 includes a pair of PMOS transistors (T1, T2) and a pair of NMOS transistors (T3, T4). The transistors (T1, T4) are connected to the Vdd node and ground nodes, respectively, and are controlled by the control signal (Vctrl). The transistors (T2, T3) are connected between the transistors (T1, T4), are controlled by the input clock signal (INtx), and provide a single-ended input signal (IN) as an output.

In an exemplary operation, when the duty cycle of the input clock signal (INtx) is less than 50%, the control signal (Vctrl) transitions from a high logic level to a low logic level. Consequently, the single-ended input signal (IN) spends more time in the high state, thus increasing its duty cycle. Conversely, when the duty cycle of the input clock signal (INtx) is greater than 50%, the control signal (Vctrl) transitions from a low logic level to a high logic level. As a result, the single-ended input signal (IN) spends more time in the low state, thereby decreasing its duty cycle. However, when the duty cycle of the single-ended input signal (IN) is substantially 50%, the control signal (Vctrl) remains at a logic level that maintains the duty cycle of the single-ended input signal (IN) without alteration.

Various configurations for the duty cycle altering circuit 310 are contemplated in further embodiments, so long as such various configurations achieve the intended purpose described above for the duty cycle altering circuit 310.

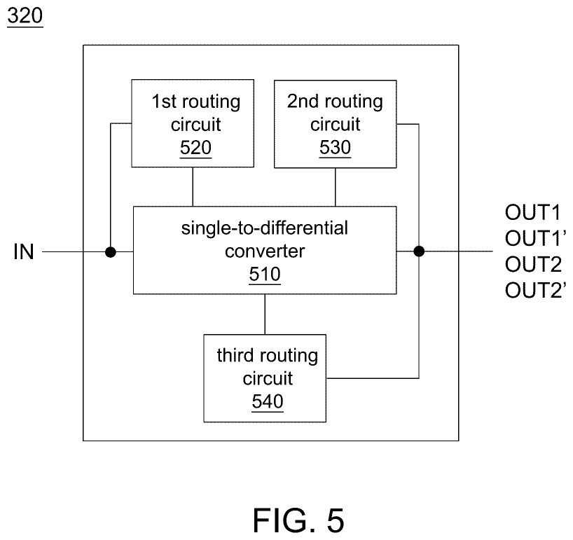

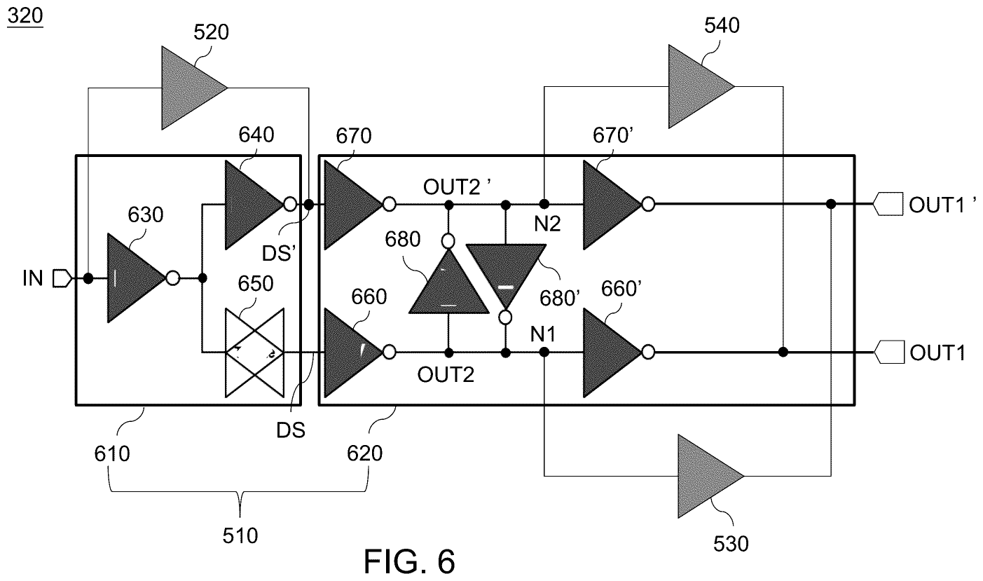

FIG. 5 is a block diagram of an exemplary differential signal generator 320 in accordance with various embodiments of the present disclosure. As illustrated in FIG. 5, the differential signal generator 320 includes a single-to-differential converter 510 and first, second, and third routing circuits 520, 530, 540. The single-to-differential converter 510 receives a single-ended input signal (IN) and (i) converts or transforms the signal-ended input signal (IN) into differential output signals, e.g., differential output signals (DS, DS′) of FIG. 6, that are substantially a hundred and eighty degrees out of phase from each other (e.g., one of the output signals DS, DS′ is low or has a logic state ‘0’ and the other of the output signals DS, DS′ is high or has a logic state ‘1’, and (ii) amplifies the differential output signals (DS, DS′) as first complementary output signals (OUT1, OUT1′) and second complementary output signals (OUT2, OUT2′).

At least one of the first, second, and third routing circuits 520, 530, 540 contributes to a substantially 50% duty cycle, e.g., from about 49% duty cycle to about 51% duty cycle, for the complementary output signals (OUT, OUT′) and a relatively short delay, e.g., from about −1 ps to about 1 ps, between the rising (or falling) edge of the complementary output signal (OUT) and the falling (or rising) edge of the complementary output signal (OUT′). For example, the first routing circuit 520 facilitates the transformation of the single-ended input signal (IN) into the differential output signal (DS′) at substantially the same time as the transformation of the single-ended input signal (IN) into the differential output signal (DS). Each of the second and third routing circuits 530, 540 facilitates the faster transformation of a respective one of the differential output signals (DS, DS′) into a respective one of the complementary output signals (OUT1, OUT1′).

FIG. 6 is a circuit diagram of another exemplary differential signal generator 320 in accordance with various embodiments of the present disclosure. As illustrated in FIG. 6, the differential signal generator 320 includes a converting circuit 610 and an isolating circuit 620. The converting circuit 610 converts or transforms the single-ended input signal (IN) into differential output signals (DS, DS′). In this exemplary embodiment, the converting circuit 610 includes first and second inverters 630, 640 and a transmission gate 650. The inverter 630 isolates the input of the differential signal generator 320 from devices external to the differential signal generator 320, receives the single-ended input signal (IN), and generates an inverted version of the single-ended input signal (IN).

The transmission gate 650 is connected between the inverter 630 and the isolating circuit 620. When activated by the enable signals at the control terminals of the transmission gate 650, the inverted version of the single-ended input signal (IN) flows from the input of the transmission gate to the output of the transmission gate 650. The inverted version of the single-ended input signal (IN) at the output of the transmission gate 650 serves as the differential output signal (DS). Conversely, when deactivated by the enable signals at the control terminals of the transmission gate 650, the transmission gate 650 inhibits flow of the inverted version of the single-ended input signal (IN) therethrough. The inverter 640 is connected between the inverter 630 and the isolating circuit 620, receives the inverted version of the single-ended input signal (IN), and generates the differential output signal (DS′).

The isolating circuit 620 isolates the output of the differential signal generator 320 from devices external to the differential signal generator 320, amplifies the differential output signals (DS, DS′), and generates the complementary output signals (OUT1, OUT1′, OUT2, OUT2′). In this exemplary embodiment, the isolating circuit 620 includes a first pair of inverters 660, 660′, a second pair of inverters 670, 670′, and a third pair of inverters 680, 680′. The inverters 660, 660′ are connected in series to the output of the transmission gate 650, amplifies the differential output signal (DS), and provides the complementary output signal (OUT1) as an output. The inverters 670, 670′ are connected in series to the output of the inverter 640, amplifies the differential output signal (DS′), and provides the complementary output signal (OUT1′) as an output. The inverters 680, 680′ are connected in a cross-coupled manner between a first node (N1) between the inverters 660, 660′ and a second node (N2) between the inverters 670, 670′ and adjusts the inverted version of the differential output signal (DS) closer to logic state ‘0’ (or ‘1’) and the inverted version of the differential output signal (DS′) closer to logic state ‘1’ (or ‘0’). The isolating circuit 620 generates the complementary output signals (OUT2, OUT2′) at the first and second nodes (N1, N2) thereof, respectively.

Inverters have a longer signal propagation delay than transmission gates. As such, the single-ended input signal (IN) traverses through the inverters 630, 640 slower than through the inverter 630 and the transmission gate 650. That is, the differential output signal (DS) arrives at the output of the transmission gate 650 earlier than the differential output signal (DS′) at the output of the inverter 640. This distorts the duty cycle of the complementary output signals (OUT1, OUT1′, OUT2, OUT2′), i.e., causes the duty cycle of the complementary output signal (OUT1, OUT1′, OUT2, OUT2′) to deviate from the ideal 50% duty cycle, and undesirably lengthens the delay between the rising (or falling) edge of the output signal (OUT1, OUT2) and the falling (or rising) edge of the output signal (OUT1′, OUT2′).

The routing circuit 520 ensures the substantially simultaneous arrival of the differential output signal (DS) at the output of the transmission gate 650 and the differential output signal (DS′) at the output of the inverter 640. For example, the routing circuit 520 is connected between the input of the inverter 630 and the output of the inverter 640 and has a shorter signal propagation delay than the inverters 630, 640. This shorter signal propagation delay of the routing circuit 640 compensates for the longer signal propagation delay of the inverters 630, 640. That is, the signal propagation delay of the inverters 630, 640 and the routing circuit 540 is substantially equal to the average of the shorter signal propagation delay of the routing circuit 540 and the longer signal propagation delay of the inverters 630, 640. This allows the substantially simultaneous arrival of the differential output signal (DS) at the output of the transmission gate 650 and the differential output signal (DS′) at the output of the second inverter 640. This helps in minimizing, if not in elimination, of the distortion to the duty cycle of the complementary output signals (OUT1, OUT1′, OUT2, OUT2′) and the delay between the rising (or falling) edge of the complementary output signal (OUT1, OUT2) and the falling (or rising) edge of the complementary output signal (OUT1′, OUT2′).

In this exemplary embodiment, the routing circuit 520 includes a buffer. For example, the buffer includes a transistor, e.g., a field-effect transistor, in a source-follower structure and having a gate terminal connected to the input of the inverter 630, a source terminal connected to the output of the inverter 640, and a drain terminal connected to ground.

Various configurations for the routing circuit 520 are contemplated in further embodiments, so long as such various configurations achieve the intended purpose described above for the routing circuit 520. For example, in some embodiments, instead of the buffer, the routing circuit 520 includes a resistor. In such some embodiments, the first resistor terminal of the resistor is connected to the input of the inverter 630 and the second resistor terminal of the resistor is connected to the output of the inverter 640. In other embodiments, instead of the buffer, the routing circuit 520 includes a transmission gate. In such other embodiments, the transmission gate has an input connected to the input of the inverter 630, an output connected to the output of the inverter 640, and a pair of control terminals, each receiving a control signal that enables or disables passage of the single-ended input signal (IN) therethrough.

The routing circuit 530 expedites the arrival of the complementary output signal (OUT1′) at the output of the inverter 670′. For example, the routing circuit 530 is connected between the first node (N1) and the output of the inverters 670′. The inverter 660 and the routing circuit 530 have a shorter signal propagation delay than the inverters 670, 670′. This shorter signal propagation delay of the inverter 660 and the routing circuit 530 compensates for the longer signal propagation delay of the inverters 670, 670′. That is, the signal propagation delay of the inverter 660, the inverters 570, 570′, and the routing circuit 530 is substantially equal to the average of the shorter signal propagation delay of the inverter 660 and the routing circuit 530 and the longer signal propagation delay of the inverters 670. This expedites the arrival of the complementary output signal (OUT1′) at the output of the inverter 670′. This helps in minimizing, if not in elimination, of the distortion to the duty cycle of the output signal (OUT1, OUT1′) and the delay between the rising (or falling) edge of the output signal (OUT1) and the falling (or rising) edge of the complementary output signal (OUT1′).

In this exemplary embodiment, the routing circuit 530 includes a buffer. For example, the buffer includes a transistor, e.g., a field-effect transistor, in a source-follower structure and having a gate terminal connected to the first node (N1), a source terminal connected to the output of the inverter 670′, and a drain terminal connected to ground.

Various configurations for the routing circuit 530 are contemplated in further embodiments, so long as such various configurations achieve the intended purpose described above for the routing circuit 530. For example, in some embodiments, instead of the buffer, the routing circuit 530 includes a resistor. In such some embodiments, the first resistor terminal of the resistor is connected to the first node (N1) and the second resistor terminal of the resistor is connected to the output of the inverter 570′. In other embodiments, instead of the buffer, the routing circuit 530 includes a transmission gate. In such other embodiments, the transmission gate has an input connected to the first node (N1), an output connected to the output of the inverter 670′, and a pair of control terminals, each receiving a control signal that enables or disables passage of the inverted version of the differential output signal (DS) therethrough.

Similarly, the routing circuit 540 expedites the arrival of the complementary output signal (OUT1) at the output of the inverter 660′. For example, the routing circuit 540 is connected between the second node (N2) and the output of the inverter 660′. The inverter 670 and the routing circuit 660 have a shorter signal propagation delay than the inverters 660, 660′. This shorter signal propagation delay of the inverter 670 and the routing circuit 540 compensates for the longer signal propagation delay of the inverters 660, 660′. That is, the signal propagation delay of the inverters 660, 660′, the inverter 670, and the routing circuit 540 is substantially equal to the average of the shorter signal propagation delay of the inverter 670 and the routing circuit 540 and the longer signal propagation delay of the inverters 660, 660′. This expedites the arrival of the output signal (OUT1) at the output of the inverter 660′. This helps in minimizing, if not in elimination, of the distortion to the duty cycle of the output signals (OUT1, OUT1′) and the delay between the rising (or falling) edge of the output signal (OUT1) and the falling (or rising) edge of the complementary output signal (OUT1′).

In this exemplary embodiment, the routing circuit 540 includes a buffer. For example, the buffer includes a transistor, e.g., a field-effect transistor, in a source-follower structure and having a gate terminal connected to the second node (N2), a source terminal connected to the output of the inverter 660′, and a drain terminal connected to ground.

Various configurations for the routing circuit 540 are contemplated in further embodiments, so long as such various configurations achieve the intended purpose described above for the routing circuit 540. For example, in some embodiments, instead of the buffer, the routing circuit 540 includes a resistor. In such some embodiments, the first resistor terminal of the resistor is connected to the second node (N2) and the second resistor terminal of the resistor is connected to the output of the inverters 660, 660′. In other embodiments, instead of the buffer, the routing circuit 540 includes a transmission gate. In such other embodiments, the transmission gate has an input connected to the second node (N2), an output connected to the output of the inverters 660, 660′, and a pair of control terminals, each receiving a control signal that enables or disables passage of the inverted version of the differential output signal (DS′) therethrough.

In some embodiments, the routing circuit 540 has substantially the same signal propagation delay as the routing circuit 530. In other embodiments, the routing circuit 540 has a shorter or longer signal propagation delay than the routing circuit 530.

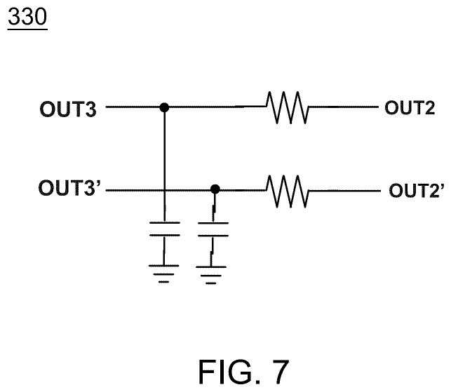

FIG. 7 is a circuit diagram of an exemplary filter circuit 330 in accordance with various embodiments of the present disclosure. As illustrated in FIG. 7, the example filter circuit 330 includes a pair of resistors and a pair of capacitors. Each resistor has a first resistor terminal that receives the respective complementary output signal (OUT2, OUT2′). Each of the capacitors is connected between the second resistor terminal of a respective one of the resistors and the ground. The second terminals of the resistors provide the complementary output signals (OUT3, OUT3′), respectively.

Various configurations for the filter circuit 330 are contemplated in further embodiments, so long as such various configurations, so long as such various configurations achieve the intended purpose described above for the filter circuit 330.

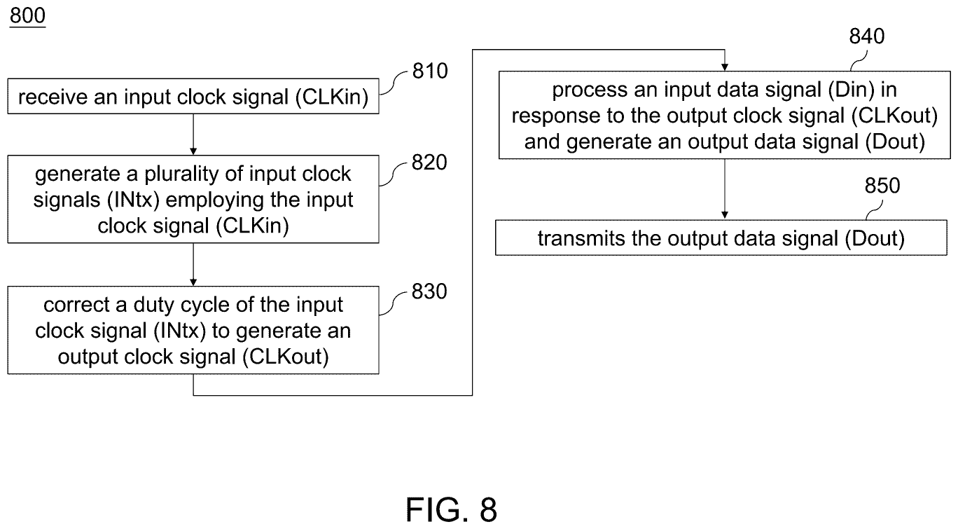

FIG. 8 is a flowchart of an exemplary method 800 for transmitting data in accordance with various embodiments of the present disclosure. The example method 800 will now be described with further reference to FIGS. 1-7 for ease of understanding. It is understood that the method 800 is applicable to structures other than those of FIGS. 1-7. Further, it is understood that additional operations can be provided before, during, and after the method 800, and some of the operations described below can be replaced or eliminated, in an alternative embodiment of the method 800.

In operation 810, the clock signal generator 230 receives an input clock signal (CLKin). In operation 820, the phase generator 230A employs the input clock signal (CLKin) to generate a plurality of input clock signals, e.g., input clock signal (INtx), each having a distinct phase. In operation 830, the duty cycle corrector 250B receives the input clock signal (INtx), corrects or adjusts the duty cycle of the input clock signal (INtx), and generates an output clock signal (CLKout) that has a substantially 50% duty cycle.

In operation 840, the transmitter circuit 240 receives an input data signal (Din), e.g., in a serial format, and processes the input data signal (Din), e.g., converts the input data signal (Din) into a parallel format, in response to the output clock signal (CLKout), e.g., a logic state (i.e., high ‘1’ or low ‘0’), a transition edge (i.e., rising or falling edge), or a clock period/frequency of the output clock signal (CLKout), whereby the transmitter circuit 240 generates an output data signal (Dout). In operation 850, the transmitter circuit 240 transmits the output data signal (Dout). In operation 860, the transmitter circuit 240 transmits an input clock signal (CLKin′) that corresponds to the input clock signal (CLKin) and that has a substantially 50% duty cycle. In certain embodiments, the transmitter circuit 240 generates the input clock signal (CLKin′) using a duty cycle corrector similar to the duty cycle corrector 230B.

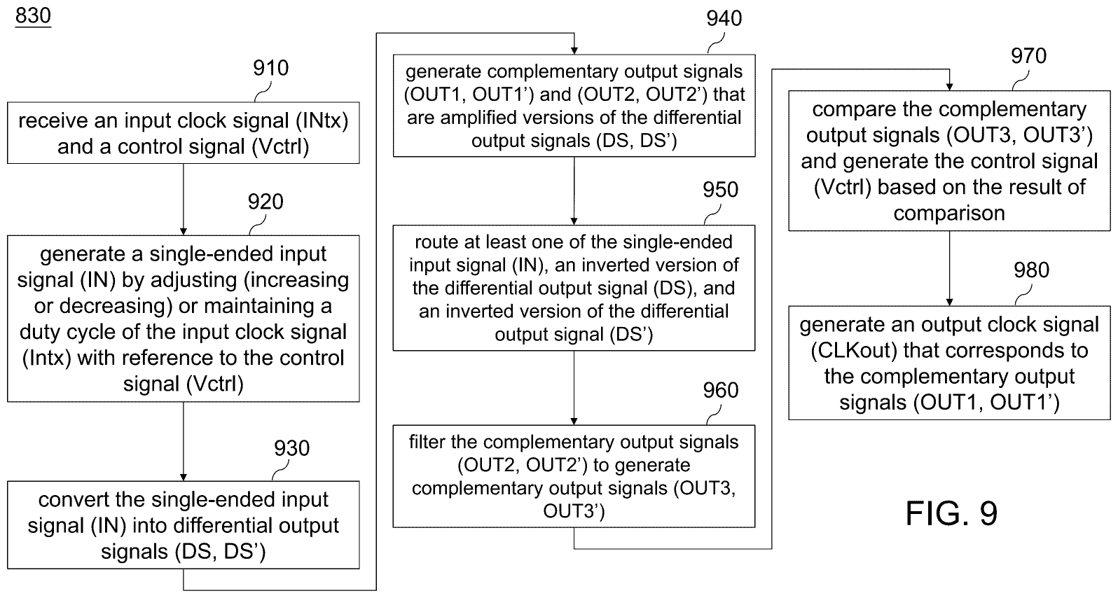

FIG. 9 is a flowchart of an exemplary operation 830 of method 800 in accordance with the present disclosure. In operation 910, the duty cycle altering circuit 310 receives an input clock signal (INtx) and a control signal (Vctrl). In operation 920, the duty cycle altering circuit 310 corrects or adjusts (increase or decrease) or maintain a duty cycle of the input clock signal (INtx) in response to the control signal (Vctrl), whereby the duty cycle altering circuit 310 generates a single-ended input signal (IN). In operation 930, the differential signal generator 320 receives the single-ended input signal (IN) and converts or transforms the single-ended input signal (IN) received thereby into differential output signals (DS, DS′). At this time, the single-ended input signal (IN) traverses through the inverters 630, 640 slower than through the inverter 630 and the transmission gate 650. That is, the differential output signal (DS) arrives at the output of the transmission gate 650 earlier than the differential output signal (DS′) at the output of the inverter 640.

In operation 940, the isolating circuit 620 amplifies the differential output signals (DS, DS′) and generates complementary output signals (OUT1, OUT1′) at the outputs of the inverters 660′, 670′, respectively, and complementary output signals (OUT2, OUT2′) at the first and second nodes (N1, N2). At this time, the differential output signal (DS) traverses through the inverters 660, 660′, whereas the differential output signal (DS′) traverses through the inverters 670, 670′.

In operation 950, the routing circuit 520 routes the single-ended input signal (IN) from the input of the inverter 630 to the output of the inverter 640. At this time, the single-ended input signal (IN) traverses through the routing circuit 520 faster than through the inverters 630, 640. This faster signal propagation of the single-ended input signal (IN) through the routing circuit 520 compensates for the slower signal propagation of the single-ended input signal (IN) through the inverters 630, 640. That is, the signal propagation of the single-ended input signal (IN) through the inverters 630, 640 and the routing circuit 520 is substantially equal to the average of the faster signal propagation of the single-ended input signal (IN) through the routing circuit 520 and the slower signal propagation of the single-ended input signal (IN) through the inverters 630, 640. This allows the substantially simultaneous arrival of the differential output signal (DS) at the output of the transmission gate 650 and the differential output signal (DS′) at the output of the inverter 640.

Subsequently, the routing circuit 530 routes an inverted version of the differential output signal (DS) from the first node (N1) to the output of the inverter 670′. At this time, the differential output signal (DS) traverses through the inverter 660 and the routing circuit 530 faster than the differential output signal (DS′) through the inverters 670, 670′. This faster signal propagation of the differential output signal (DS) through the inverter 660 and the routing circuit 530 compensates for the slower signal propagation of the differential output signal (DS′) through the inverters 670, 670′. This expedites the arrival of the complementary output signal (OUT1′) at the output of the inverter 670′.

Next, the routing circuit 540 routes an inverted version of the differential output signal (DS′) from the second node (N2) to the output of the inverter 660′. At this time, the differential output signal (DS′) traverses through the inverter 670 and the routing circuit 540 faster than the differential output signal (DS) through the inverters 660, 660′. This faster signal propagation of the differential output signal (DS′) through the inverter 670 and the routing circuit 540 compensates for the slower signal propagation of the differential output signal (DS) through the inverters 660, 660′. This expedites the arrival of the complementary output signal (OUT1) at the output of the inverter 660′.

In operation 960, the filter circuit 330 allows the complementary output signal (OUT2, OUT2′) with frequencies below a predetermined cutoff frequency to pass through, while attenuating the complementary output signal (OUT2, OUT2′) with frequencies above the predetermined cutoff frequency. As a result, the filter circuit 330 generates complementary output signals (OUT3, OUT3′), each of which corresponds to a respective one of the complementary output signals (OUT2, OUT2′). In operation 970, the comparator 340 receives the complementary output signal (OUT2) at the inverting input terminal (or non-inverting input terminal) thereof and the complementary output signal (OUT2′) at the non-inverting input terminal (or inverting input terminal) thereof, compares the complementary output signals (OUT2, OUT2′), and generates a control signal (Vctrl) that indicates the result of comparison. In operation 980, the clock signal generator 230 generates an output clock signal (CLKout) that corresponds to the complementary output signals (OUT1, OUT1′).

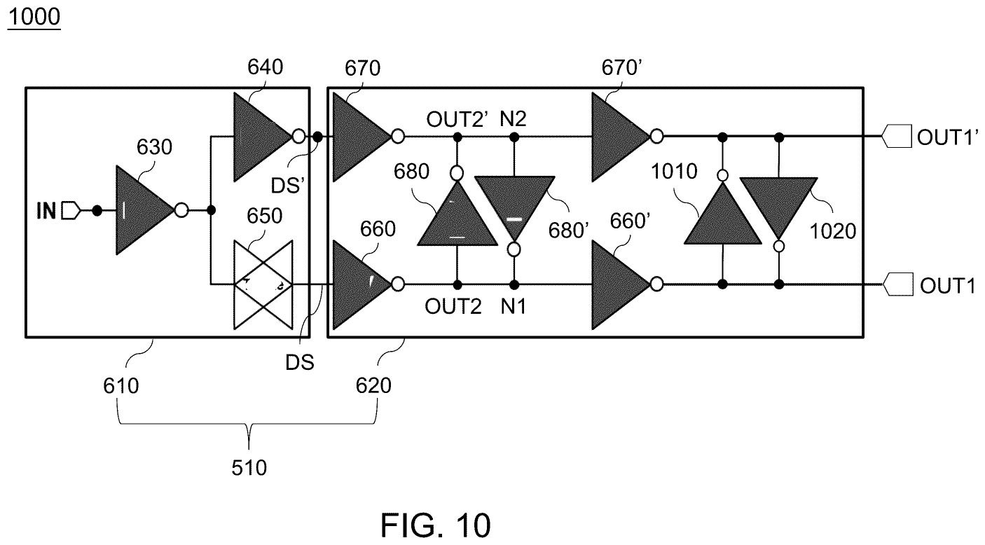

Although the differential signal generator 320 is exemplified with three routing circuits 520, 530, 540, it should be understood that, after reading this disclosure, the number of routing circuits of the differential signal generator 320 may be increased or decreased as desired. For example, in some embodiments, the differential signal generator 320 is dispensed with one of the routing circuits 520, 530, 540. In such some embodiments, the differential signal generator 320 may include the routing circuit 520 but not at least one of the routing circuits 430, 440 or vice versa. In other embodiments, the differential signal generator 320 does not include a routing circuit. For example, FIG. 10 is a circuit diagram of another exemplary differential signal generator 1000 in accordance with various embodiments of the present disclosure. As illustrated in FIG. 10, the example differential signal generator 1000 of FIG. 10 differs from the differential signal generator 320 of FIG. 5 in that differential signal generator 1000 excludes the routing circuit 520, 530, 540. In addition, the differential signal generator 1000 further includes cross-coupled inverters 1010, 1020 connected across the output of the inverter 660′ and the output of the inverter 670′.

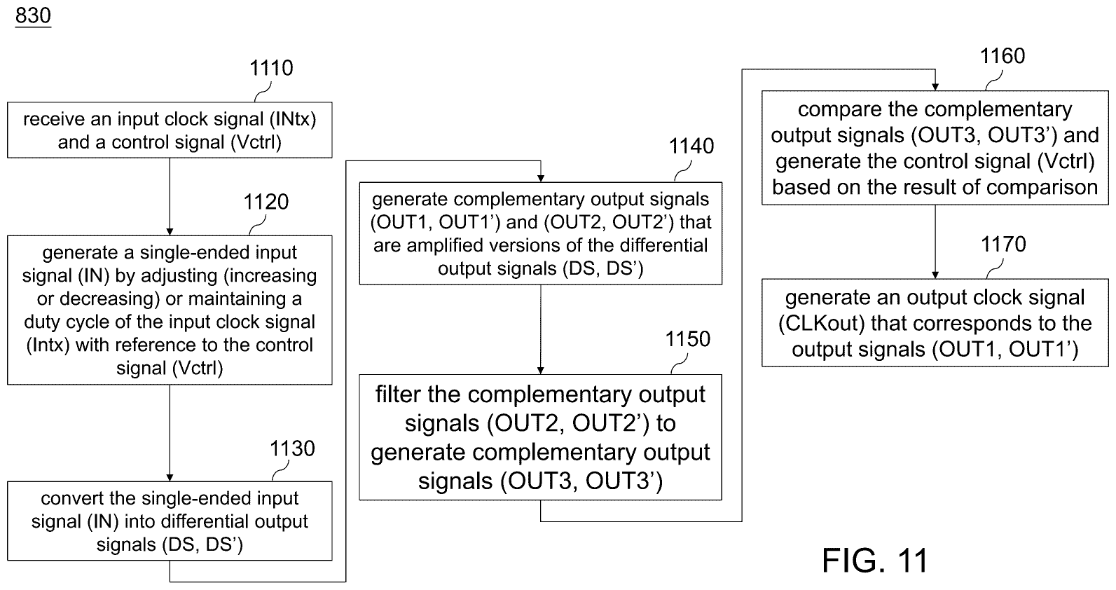

FIG. 11 is a flowchart of another exemplary operation 830 of method 800 in accordance with the present disclosure. In operation 1110, the duty cycle altering circuit 310 receives an input clock signal (INtx) and a control signal (Vctrl). In operation 1120, the duty cycle altering circuit 310 corrects or adjusts (increase or decrease) or maintain a duty cycle of the input clock signal (INtx) with reference to the control signal (Vctrl), whereby the duty cycle altering circuit 310 generates a single-ended input signal (IN). In operation 1130, the differential signal generator 320 receives the single-ended input signal (IN) and converts or transforms the single-ended input signal (IN) received thereby into differential output signals (DS, DS′). At this time, the single-ended input signal (IN) traverses through the inverters 630, 640 slower than through the inverter 630 and the transmission gate 650. That is, the differential output signal (DS) arrives at the output of the transmission gate 650 earlier than the differential output signal (DS′) at the output of the inverter 640.

In operation 1140, the isolating circuit 620 amplifies the differential output signals (DS, DS′) and generates complementary output signals (OUT1, OUT1′) at the outputs of the inverters 660′, 670′, respectively, and complementary output signals (OUT2, OUT2′) at the first and second nodes (N1, N2). At this time, the differential output signal (DS) traverses through the inverters 660, 660′, whereas the differential output signal (DS′) traverses through the inverters 670, 670′.

In operation 1150, the filter circuit 330 allows the complementary output signal (OUT2, OUT2′) with frequencies below a predetermined cutoff frequency to pass through, while attenuating the complementary output signal (OUT2, OUT2′) with frequencies above the predetermined cutoff frequency, and generates complementary output signals (OUT3, OUT3′), each of which corresponds to a respective one of the complementary output signals (OUT2, OUT2′). In operation 1160, the comparator 340 receives the complementary output signal (OUT2) at the inverting input terminal (or non-inverting input terminal) thereof and the complementary output signal (OUT2′) at the non-inverting input terminal (or inverting input terminal) thereof, compares the complementary output signals (OUT2, OUT2′), and generates an input control signal (Vctrl) that indicates the result of comparison. In operation 1170, the clock signal generator 230 generates an output clock signal (CLKout) that corresponds to the complementary output signals (OUT1, OUT1′).

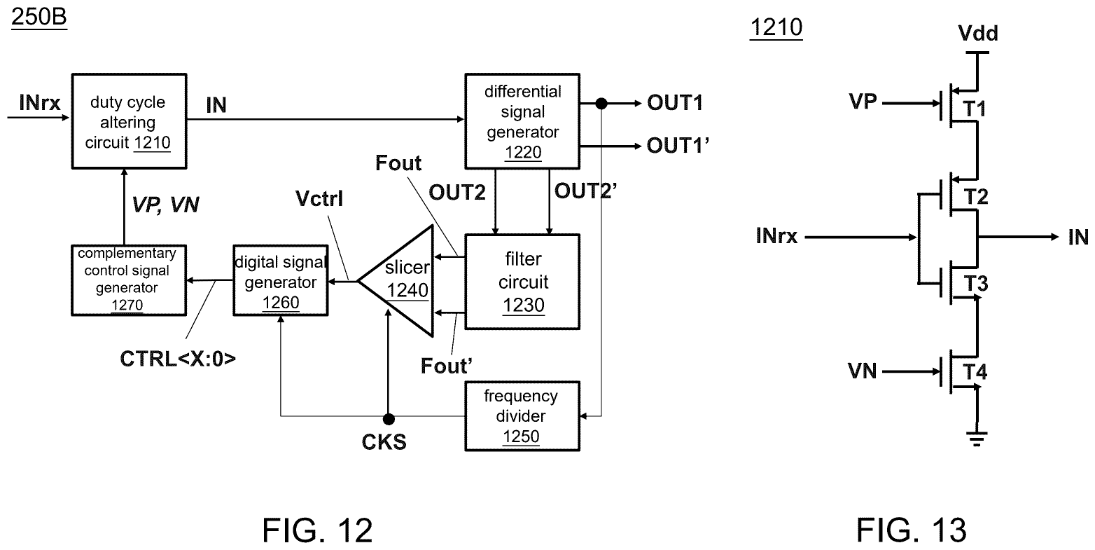

FIG. 12 is a block/circuit diagram illustrating another exemplary duty cycle corrector 250B in accordance with various embodiments of the present disclosure. As illustrated in FIG. 12, the example duty cycle corrector 250B is in the form of a digital circuit and includes a duty cycle altering circuit 1210, a differential signal generator 1220, a filter circuit 1230, a slicer 1240, a frequency divider 1250, a digital signal generator 1260, and a complementary control signal generator 1270. The duty cycle altering circuit 1210 receives an input clock signal (INrx) and complementary control signals (VP, VN), adjusts (increases or decreases) or maintains the duty cycle of the input clock signal (INrx) in response to the complementary control signals (VP, VN), and generates a single-ended input signal (IN). The differential signal generator 1220 receives the single-ended input signal (IN) and converts or transforms the single-ended input signal (IN) into first complementary output signals (OUT1, OUT1′) and second complementary output signals (OUT2, OUT2′). The output clock signal (CLKout′) is associated with the complementary output signals (OUT1, OUT1′).

The filter circuit 1230 receives the complementary output signal (OUT2, OUT2′) and includes a low pass filter, allowing the complementary output signals (OUT2, OUT2′) with frequencies below a predetermined cutoff frequency to pass through, while attenuating the output signals (OUT2, OUT2′) with frequencies above the predetermined cutoff frequency, and generates complementary output signals (OUT3, OUT3′), each of which corresponds to a respective one of the complementary output signals (OUT2, OUT2′). In some embodiments, the filter circuit 1230 includes a high pass filter. In such some embodiments, the filter circuit 1230 permits the complementary output signals (OUT2, OUT2′) with frequencies above a predetermined cutoff frequency to pass through, while attenuating the complementary output signals (OUT2, OUT2′) with frequencies below the predetermined cutoff frequency. In other embodiments, the filter circuit 1230 includes a bandpass filter. In such other embodiments, the filter circuit 1230 enables the complementary output signals (OUT2, OUT2′) with frequencies inside a predetermined frequency range to pass through, while attenuating the complementary output signals (OUT2, OUT2′) with frequencies outside the predetermined frequency range.

The frequency divider 1250 receives the complementary output signal (OUT1) and generates a clock signal (CKS) that has a lower frequency than the complementary output signal (OUT1). The slider 1240, e.g., an operational amplifier, receives one of the complementary output signals (OUT3, OUT3′) at a non-inverting input thereof and the other of the complementary output signals (OUT3, OUT3′) at an inverting input thereof, compares the complementary output signals (OUT3, OUT3′) received thereby, and generates a control signal (Vctrl) that indicates the result of comparison in response to the clock signal (CKS), e.g., a logic state (i.e., high ‘1’ or low ‘0’), a transition edge (i.e., rising or falling edge), or a clock period/frequency of the output clock signal (CKS).

The digital signal generator 1260, e.g., a finite state machine (FSM), receives the control signal (Vctrl) and generates a digital signal (CTRL<x:0>) that represents the control signal (Vctrl) in response to the clock signal (CKS), e.g., a logic state (i.e., high ‘1’ or low ‘0’), a transition edge (i.e., rising or falling edge), or a clock period/frequency of the output clock signal (CKS). The complementary control signal generator 1270 receives the digital signal (CTRL<x:0>) and generates the complementary control signals (VP, VN), in a manner that will be describe further below.

FIG. 13 is a circuit diagram of another exemplary duty cycle altering circuit 1210 in accordance with various embodiments of the present disclosure. As illustrated in FIG. 13, the example duty cycle altering circuit 1210 includes a pair of PMOS transistors (T1, T2) and a pair of NMOS transistors (T3, T4). Each of the transistors (T1, T4) is connected to a respective one of the Vdd and ground nodes and is controlled by a respective one of the complementary control signals (VP, VN). The transistors (T2, T3) are connected between the transistors (T1, T4), are controlled by the input clock signal (INrx), and provide a single-ended input signal (IN) as an output.

In an exemplary operation, when the duty cycle of the input clock signal (INrx) is less than 50%, the control signal (VP) transitions from a high logic level to a low logic level and the control signal (VN) transitions from a low logic level to a high logic level. Consequently, the single-ended input signal (IN) spends more time in the high state, thus increasing its duty cycle. Conversely, when the duty cycle of the input clock signal (INrx) is greater than 50%, the control signal (VP) transitions from a low logic level to a high logic level and the control signal (VN) transitions from a high logic level to a low logic level. As a result, the single-ended input signal (IN) spends more time in the low state, thereby decreasing its duty cycle. However, when the duty cycle of the single-ended input signal (IN) is substantially 50%, the control signal (VP, VN) remains at a logic level that maintains the duty cycle of the single-ended input signal (IN) without alteration.

Various configurations for the duty cycle altering circuit 1210 are contemplated in further embodiments, so long as such various configurations achieve the intended purpose described above for the duty cycle altering circuit 1210.

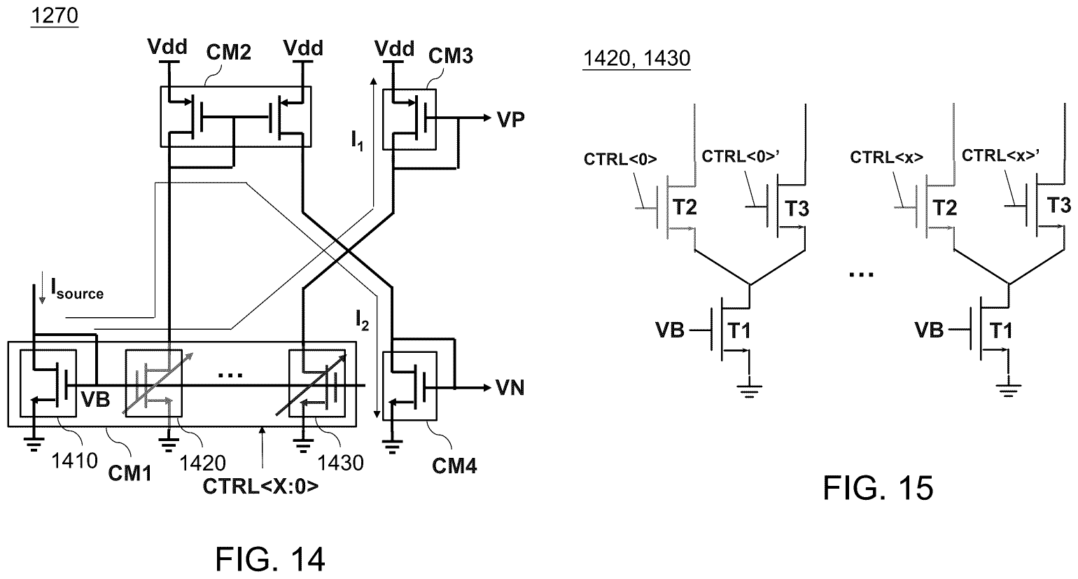

FIG. 14 is a circuit diagram of an exemplary complementary control signal generator 1270 in accordance with various embodiments of the present disclosure. As illustrated in FIG. 14, the example complementary control signal generator 1270 includes a plurality of current mirror circuits (CM1-CM4). A current mirror circuit replicates (or “mirrors”) a current from one active device, e.g., a master transistor 1410, to another, e.g., one or more slave transistors 1420, 1430. In certain embodiments, a current through a slave transistor is a multiple of a current through a master transistor. The current mirror circuits (CM1, CM2) are connected in series with each other and between the Vdd and ground nodes. The current mirror circuits (CM1, CM3) are connected in series with each other and between the Vdd and ground nodes. The current mirror circuits (CM2, CM4) are connected in series with each other and between the Vdd and ground nodes.

In an exemplary operation, when the current mirror circuit (CM1) is activated by an activating signal (VB), e.g., generated by a voltage source, when a source current (I_{source}), e.g., generated by a current source, flows through the master transistor 1410, and when the digital signal (CTRL<x:0>) turns on/off one or more slave transistors 1420 and one or more slave transistors 1430, a first current (I₁) flows through the current mirror circuits (CM1, CM3). At substantially the same time, a second current (I₂) flows through the current mirror circuits (CM1, CM2, CM4). As a result, the control signal (VP, VN) is increased or decreased depending on the number of slave transistors 1420, 1430 turned on/off by the digital signal (CTRL<x: 0>).

FIG. 15 is a circuit diagram of an exemplary slave transistors 1420, 1430 in accordance with various embodiments of the present disclosure. As illustrated in FIG. 15, the example slave transistors 1420, 1430 include a plurality of first transistors (T1), a plurality of second transistors (T2), and a plurality of third transistors (T3). Each transistor (T1) has a first source/drain terminal connected to the ground node and a gate terminal that receives an activating signal (VB). Each transistor (T2) has a source/drain terminal connected to a second source/drain terminal of the respective transistor (T1) and a gate terminal that receives the digital signal (CTRL<x:0>). Likewise, each transistor (T3) has a source/drain terminal connected to the second source/drain terminal of the respective transistor (T1) and a gate terminal that receives the inverted version of the digital signal (CTRL<x:0>).

Various configurations for the complementary control signal generator 1270 are contemplated in further embodiments, so long as such various configurations achieve the intended purpose described above for the complementary control signal generator 1270.

Because the structures and operations of the differential signal generator 1220 and the filter circuit 1230 of the duty cycle corrector 230B are similar to those of the duty cycle corrector 250B, a detailed description thereof is omitted herein for the sake of brevity.

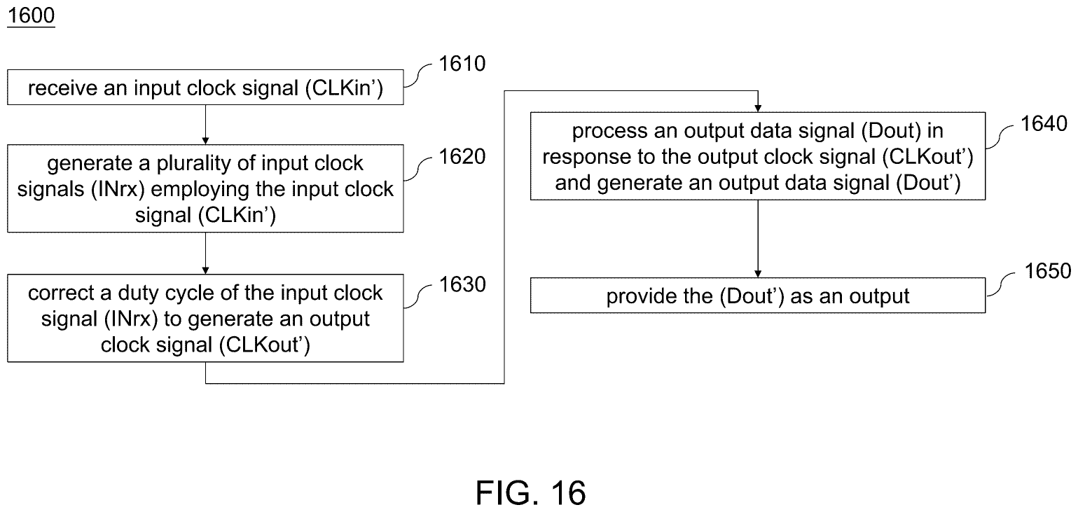

FIG. 16 is a flowchart of an exemplary method 1600 for receiving data in accordance with various embodiments of the present disclosure. The example method 1600 will now be described with further reference to FIGS. 1, 2, 5-7, 10, and 12-15 for ease of understanding. It is understood that the method 1600 is applicable to structures other than those of FIGS. 1, 2, 5-7, 10, and 12-15. Further, it is understood that additional operations can be provided before, during, and after the method 1600, and some of the operations described below can be replaced or eliminated, in an alternative embodiment of the method 1600.

In operation 1610, the clock signal generator 250 receives an input clock signal (CLKin′). In operation 1620, the phase generator 250A employs the input clock signal (CLKin′) to generate a plurality of input clock signals, e.g., input clock signal (INrx), each having a distinct phase. In operation 1230, the duty cycle corrector 250B receives the input clock signal (INtx), corrects or adjusts the duty cycle of the input clock signal (INrx), and generates an output clock signal (CLKout′) that has a substantially 50% duty cycle.

In operation 1640, the receiver circuit 260 receives an output data signal (Dout), e.g., in a parallel format, and processes the output data signal (Dout), e.g., converts the output data signal (Dout) into a serial format, in response to the output clock signal (CLKout′), e.g., a logic state (i.e., high ‘1’ or low ‘0’), a transition edge (i.e., rising or falling edge), or a clock period/frequency of the output clock signal (CLKout′), whereby the receiver circuit 260 generates an output data signal (Dout′). In operation 1650, the receiver circuit 260 provides the output data signal (Dout′) as an output.

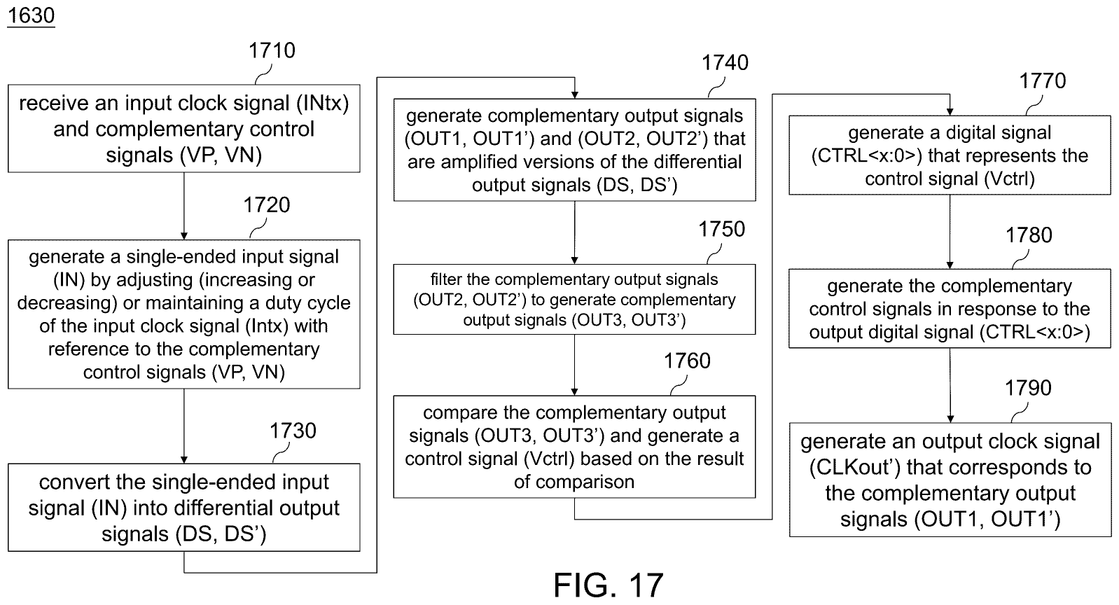

FIG. 17 is a flowchart of an exemplary operation 1630 of method 1600 in accordance with the present disclosure. In operation 1710, the duty cycle altering circuit 1210 receives an input clock signal (INrx) and complementary control signals (VP, VN). In operation 1720, the duty cycle altering circuit 1210 corrects or adjusts (increase or decrease) or maintain a duty cycle of the input clock signal (INrx) in response to the complementary control signals (VP, VN), whereby the duty cycle altering circuit 1210 generates a single-ended input signal (IN). In operation 1730, the differential signal generator 1220 receives the single-ended input signal (IN) and converts or transforms the single-ended input signal (IN) received thereby into differential output signals (DS, DS′). At this time, the single-ended input signal (IN) traverses through the inverters 630, 640 slower than through the inverter 630 and the transmission gate 650. That is, the differential output signal (DS) arrives at the output of the transmission gate 650 earlier than the differential output signal (DS′) at the output of the inverter 640.

In operation 1740, the isolating circuit 620 amplifies the differential output signals (DS, DS′) and generates complementary output signals (OUT1, OUT1′) at the outputs of the inverters 660′, 670′, respectively, and complementary output signals (OUT2, OUT2′) at the first and second nodes (N1, N2). At this time, the differential output signal (DS) traverses through the inverters 660, 660′, whereas the differential output signal (DS′) traverses through the inverters 670, 670′.

In some embodiments, the routing circuit 520 routes the single-ended input signal (IN) from the input of the inverter 630 to the output of the inverter 640. At this time, the single-ended input signal (IN) traverses through the routing circuit 520 faster than through the inverters 630, 640. This faster signal propagation of the single-ended input signal (IN) through the routing circuit 520 compensates for the slower signal propagation of the single-ended input signal (IN) through the inverters 630, 640. That is, the signal propagation of the single-ended input signal (IN) through the inverters 630, 640 and the routing circuit 520 is substantially equal to the average of the faster signal propagation of the single-ended input signal (IN) through the routing circuit 520 and the slower signal propagation of the single-ended input signal (IN) through the inverters 630, 640. This allows the substantially simultaneous arrival of the differential output signal (DS) at the output of the transmission gate 650 and the differential output signal (DS′) at the output of the inverter 640.

Subsequently, the routing circuit 530 routes an inverted version of the differential output signal (DS) from the first node (N1) to the output of the inverter 670′. At this time, the differential output signal (DS) traverses through the inverter 660 and the routing circuit 530 faster than the differential output signal (DS′) through the inverters 670, 670′. This faster signal propagation of the differential output signal (DS) through the inverter 660 and the routing circuit 530 compensates for the slower signal propagation of the differential output signal (DS′) through the inverters 670, 670′. This expedites the arrival of the complementary output signal (OUT1′) at the output of the inverter 670′.

Next, the routing circuit 540 routes an inverted version of the differential output signal (DS′) from the second node (N2) to the output of the inverter 660′. At this time, the differential output signal (DS′) traverses through the inverter 670 and the routing circuit 540 faster than the differential output signal (DS) through the inverters 660, 660′. This faster signal propagation of the differential output signal (DS′) through the inverter 670 and the routing circuit 540 compensates for the slower signal propagation of the differential output signal (DS) through the inverters 660, 660′. This expedites the arrival of the complementary output signal (OUT1) at the output of the inverter 660′.

In other embodiments, the frequency divider 1250 divides the frequency of the complementary output signal (OUT), whereby the frequency divider 1250 generates a clock signal (CKS) that has a lower frequency than the complementary output signal (OUT1). In operation 1750, in response to the clock signal (CKS), the filter circuit 1230 allows the complementary output signal (OUT2, OUT2′) with frequencies below a predetermined cutoff frequency to pass through, while attenuating the complementary output signal (OUT2, OUT2′) with frequencies above the predetermined cutoff frequency. As a result, the filter circuit 1230 generates complementary output signals (OUT3, OUT3′), each of which corresponds to a respective one of the complementary output signals (OUT2, OUT2′). In operation 1760, in response to the input clock signal (CKS), the slicer 1240 receives the complementary output signal (OUT2) at the inverting input terminal (or non-inverting input terminal) thereof and the complementary output signal (OUT2′) at the non-inverting input terminal (or inverting input terminal) thereof, compares the complementary output signals (OUT2, OUT2′), and generates a control signal (Vctrl) that indicates the result of comparison. In operation 1770, in response to the input clock signal (CKS), the digital signal generator 1260 receives the control signal (Vctrl) and generates a digital signal (CTRL<x:0>) that represents the control signal (Vctrl). In operation 1780, in response to the digital signal (CTRL<x:0>), the complementary control signal generator 1270 generates the complementary control signal (VP, VN). In operation 1790, the clock signal generator 230 generates an output clock signal (CLKout′) that corresponds to the complementary output signals (OUT1, OUT1′).

In an embodiment, a device comprises a clock signal generator and a transmitter circuit. The clock signal generator receives a first input clock signal, generates an output clock signal, and includes a phase generator and a duty cycle corrector. The phase generator generates a plurality of second input clock signals from the first input clock signal. Each second input clock signal has a distinct phase. The duty cycle corrector includes a duty cycle altering circuit, a differential signal generator, and a comparator. The duty cycle altering circuit adjusts a duty cycle of the second input clock signal with reference to a control signal and generates a single-ended input signal. The differential signal generator generates complementary output signals from the single-ended input signal. The comparator compares the complementary output signals and generates a result of comparison that serves as the control signal. The transmitter circuit receives an input data signal, processes the input data signal in response to the output clock signal, generates an output data signal, and transmits the output data signal.

In another embodiment, a device comprises a clock signal generator and a receiver circuit. The clock signal generator receives a first input clock signal, generates an output clock signal, and includes a phase generator and a duty cycle corrector. The phase generator generates a plurality of second input clock signals from the input clock signal. Each second input clock signal has a distinct phase. The duty cycle corrector includes a duty cycle altering circuit, a differential signal generator, a comparator, a digital signal generator, and a complementary signal generator. The duty cycle altering circuit adjusts a duty cycle of the second input clock signal with reference to complementary control signals and generates a single-ended input signal (IN). The differential signal generator converts the single-ended input signal into complementary output signals. The comparator compares the complementary output signals and generates a control signal that indicates a result of comparison. The digital signal generator generates an output digital signal that represents the control signal. The complementary signal generator generates the complementary control signals in response to the digital signal. The receiver circuit receives a first output data signal, processes the first output data signal in response to the output clock signal, generates a second output data signal, and provides the second output data signal as an output.

In another embodiment, a method comprises, for correcting a duty cycle of a signal, comprising: receiving a first input signal; generating a second input clock signal associated with the first input signal; generating a single-ended input signal by adjusting a duty cycle of the second input clock signal with reference to a first control signal; converting the single-ended input signal into first complementary output signals; comparing the first complementary output signals; and generating the first control signal based on a result of comparison.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a clock signal generator configured to receive a first input clock signal and to generate an output clock signal and including:
a phase generator configured to generate a plurality of second input clock signals from the first input clock signal, each second input clock signal having a distinct phase;
a duty cycle corrector including:
a duty cycle altering circuit configured to adjust a duty cycle of the second input clock signal with reference to a control signal and to generate a single-ended input signal;
a differential signal generator configured to generate complementary output signals from the single-ended input signal; and
a comparator configured to compare the complementary output signals and to generate a result of comparison that serves as the control signal; and
a transmitter circuit configured to receive an input data signal, to process the input data signal in response to the output clock signal, to generate an output data signal, and to transmit the output data signal.

2. The device of claim 1, wherein the differential signal generator includes:
a converting circuit configured to convert the single-ended input signal into differential output signals; and
an isolating circuit connected to converting circuit and configured to generate the complementary output signals that are amplified versions of the differential output signals, respectively.

3. The device of claim 2, wherein the differential signal generator further includes a routing circuit connected between an input and an output of the converting circuit and configured to compensate a delay introduced by the converting circuit.

4. The device of claim 2, wherein the differential signal generator further includes a routing circuit connected between an input and an output of the isolating circuit and configured to compensate a delay introduced by the isolating circuit.

5. The device of claim 2, wherein:
the converting circuit includes a first inverter and a second inverter connected in series with the first inverter; and
a transmission gate connected between an input and an output of the second inverter.

6. The device of claim 2, wherein the isolating circuit includes:
a first inverter;
a second inverter connected between the converting circuit and the first inverter;
a third inverter;
a fourth inverter connected between the converting circuit and the third inverter; and
cross-coupled inverters connected between an output of the second inverter and an output of the fourth inverter.

7. The device of claim 1, further comprising a filter circuit connected between the differential signal generator and the comparator.

8. A device comprising:
a clock signal generator configured to receive a first input clock signal and to generate an output clock signal and including:
a phase generator configured to generate a plurality of second input clock signals from the input clock signal, each second input clock signal having a distinct phase;
a duty cycle corrector including:
a duty cycle altering circuit configured to adjust a duty cycle of the second input clock signal with reference to complementary control signals and to generate a single-ended input signal;
a differential signal generator configured to convert the single-ended input signal into complementary output signals;
a comparator configured to compare the complementary output signals and to generate a control signal that indicates a result of comparison;
a digital signal generator configured to generate a digital signal that represents the control signal; and
a complementary signal generator configured to generate the complementary control signals in response to the digital signal; and
a receiver circuit configured to receive a first output data signal, to process the first output data signal in response to the output clock signal, to generate a second output data signal, and to provide the second output data signal as an output.

9. The device of claim 8, wherein the differential signal generator includes:
a converting circuit configured to convert the single-ended input signal into differential output signals; and
an isolating circuit connected to converting circuit and configured to generate the complementary output signals that are amplified versions of the differential output signals, respectively.

10. The device of claim 9, wherein the differential signal generator further includes a routing circuit connected between an input and an output of the converting circuit and configured to compensate a delay introduced by the converting circuit.

11. The device of claim 9, wherein the differential signal generator further includes a routing circuit connected between an input and an output of the isolating circuit and configured to compensate a delay introduced by the isolating circuit.

12. The device of claim 9, wherein:
the converting circuit includes a first inverter and a second inverter connected in series with the first inverter; and
a transmission gate connected between an input and an output of the second inverter.

13. The device of claim 9, wherein the isolating circuit includes:
a first inverter;
a second inverter connected between the converting circuit and the first inverter;
a third inverter;
a fourth inverter connected between the converting circuit and the third inverter; and
cross-coupled inverters connected between an output of the second inverter and an output of the fourth inverter.

14. The device of claim 8, further comprising a frequency divider connected between the differential signal generator and at least one of the comparator and the digital signal generator.

15. The device of claim 8, further comprising a filter circuit connected between the differential signal generator and the comparator.

16. A method for correcting a duty cycle of a signal, the method comprising:
receiving a first input signal;
generating a second input clock signal associated with the first input signal;
generating a single-ended input signal by adjusting a duty cycle of the second input clock signal with reference to a first control signal;
converting the single-ended input signal into first complementary output signals;
comparing the first complementary output signals; and
generating the first control signal based on a result of comparison.

17. The method of claim 16, further comprising:
adjusting the duty cycle of the second input clock signal with further reference to a second control signal that is a complement of the first control signal;
generating a digital signal that represents the result of comparison; and
generating the first and second control signals in response to the digital signal.

18. The method of claim 16, further comprising:
converting the single-ended input signal into second complementary output signals;
dividing a frequency of one of the second complementary output signals to generate a third input signal; and
generating the result of comparison in response to the third input signal.

19. The method of claim 16, further comprising attenuating the first complementary output signals with frequencies above a predetermined cutoff frequency.

20. The method of claim 16, wherein converting the single-ended input signal into first complementary output signals includes:
transforming the single-ended input signal into differential output signals; and
routing at least one of the single-ended input signal and the differential output signals.
